(19) United States
(12) Patent Application Publication
(10) Pub. No.: US 2009/0142907 A1
(43) Pub. Date: Jun. 4, 2009

(54) SEMICONDUCTOR MANUFACTURING APPARATUS AND MANUFACTURING METHOD OF SEMICONDUCTOR DEVICE

(75) Inventors: Tomoyasu KAI, Miyazaki (JP); Hiroyuki BABA, Miyazaki (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/325,024

(22) Filed: Nov. 28, 2008

(30) Foreign Application Priority Data
Nov. 30, 2007 (JP) 2007-311083

(51) Int. Cl. H01L 21/205

(52) U.S. Cl. 438/479

(57) ABSTRACT

The present invention provides means for making appropriate a preheat condition at a sapphire substrate preheating step and thereby smoothing sucking and holding of a sapphire substrate. The means includes a hot plate for heating up a sapphire substrate in the atmosphere, support portions for supporting the sapphire substrate with a back surface thereof being opposite to the hot plate and a predetermined spacing being defined therebetween, and a jet hole provided in the hot plate and for jetting gas toward a central part of the sapphire substrate. When the sapphire substrate is preheated by the hot plate, a preheat condition for the sapphire substrate is set assuming that the predetermined spacing is 1 mm or less and the jet amount of the gas from the jet hole is 20 L/min or more. An end condition for the preheat is set as the time when the temperature of the central part of the sapphire substrate becomes lower 65° C. or more than that of an outer peripheral edge portion thereof.

### BACKGROUND OF THE INVENTION

The present invention relates to a semiconductor manufacturing apparatus and a manufacturing method of a semiconductor device both employed in a step requiring preheating of a sapphire substrate in a process for manufacturing a semiconductor device using the sapphire substrate.

In general, a process for manufacturing a semiconductor device using a sapphire substrate in which a semiconductor layer composed of a thin film such as silicon (Si) or the like is laminated on a front surface of an insulated board comprised of a sapphire crystal can substantially follow a process for manufacturing a semiconductor device using a normal silicon substrate. A semiconductor manufacturing apparatus is shared and its manufacturing line can be fabricated at low cost.

When the process for manufacturing the semiconductor device using the silicon substrate is diverted for the process for manufacturing the semiconductor device using the sapphire substrate, a problem arises which is attributable to the fact that since sapphire is transparent, the rate of absorption of radiation heat based on infrared radiation or the like is low.

As to the fact that the rate of absorption of radiation heat is low, the conventional semiconductor manufacturing apparatus forms a thin film comprised of an optical absorption body or a conductor closely on the back surface of the sapphire substrate and heats the thin film by radiation heat or eddy current through a lamp heating method or a high-frequency induction heating method or the like to heat up the sapphire substrate by heat conduction from the heated thin film, thereby preheating the sapphire substrate in the corresponding process step (refer to, for example, a patent document 1 (Japanese Unexamined Patent Publication No. Hei 10(1998)-70313 (paragraph 0019 in page 4-paragraph 0032 in page 5, FIG. 3 and FIG. 4)).

When such preheat is carried out, a manufacturing process low in atmosphere temperature in the corresponding process step, e.g., a preheat process step of an atmospheric pressure CVD apparatus used in, for example, an atmospheric-pressure CVD (Chemical Vapor Deposition) method causes a problem in that when the sapphire substrate is heated from its back surface by a hot plate, for example, a temperature difference takes place between the front and back surfaces of the sapphire substrate, so that convex warpage occurs in the heated-up sapphire substrate with its central part lifted up as viewed on the hot plate side, thus falling into a difficulty in sucking and holding the back surface of the sapphire substrate by negative pressure.

In order to solve such a problem, the present applicant has proposed a technique disclosed in Japanese Patent Application No. 2006-194789, wherein during heating up of a sapphire substrate provided in a hot plate by the hot plate in a sapphire substrate preheating process step, nitrogen gas (N₂) is jetted from an intake/exhaust hole for sucking and holding the sapphire substrate to reduce the rate of a rise in the temperature of a central part of the sapphire substrate and thereby the sapphire substrate is evenly preheated while its warpage is being suppressed, and thereafter negative pressure is supplied to the intake/exhaust hole to suck and hold the back surface of the planarized sapphire substrate, after which the sapphire substrate held by the hot plate is conveyed to a deposition process step based on the CVD method, where its process work operation is carried out.

Although, however, the technique of jetting nitrogen gas from the intake/exhaust hole that shares the above suction and jet holes to cool the central part of the sapphire substrate, thereby suppressing the warpage of the sapphire substrate is effective as a technique capable of evenly preheating the sapphire substrate and smoothing holding of the planarized sapphire substrate by suction thereby to achieve an improvement in the efficiency of the process work operation, the technique rarely has a case in which the flatness of the post-suction sapphire substrate is insufficient, and involves a problem in that it leads to a reduction in the yield at the production of the semiconductor device using the sapphire substrate.

### SUMMARY OF THE INVENTION

The present invention has been made to solve the above problems. It is therefore an object of the present invention to provide means for making appropriate a preheat condition at a sapphire substrate preheating step and thereby smoothing sucking and holding of a sapphire substrate.

According to one aspect of the present invention, for attaining the above object, there is provided a semiconductor manufacturing apparatus comprising a hot plate for heating up a sapphire substrate in the atmosphere, support portions for supporting the sapphire substrate with a back surface thereof being opposite to the hot plate and a predetermined spacing being defined therebetween, and a jet hole provided in the hot plate and for jetting gas toward a central part of the sapphire substrate, wherein when the sapphire substrate is preheated by the hot plate, a preheat condition for the sapphire substrate is set assuming that the predetermined spacing is 1 mm or less and a jet amount of the gas from the jet hole is 20 L/min or more, and wherein an end condition for the preheat is set as the time when the temperature of the central part of the sapphire substrate becomes lower 65° C. or more than that of an outer peripheral edge portion thereof.

Thus, the present invention can bring about an advantageous effect in that a preheat condition at a preheat process step is made appropriate, and sucking and holding of a sapphire substrate to a hot plate can be carried out smoothly while the flatness of the sapphire substrate at its sucking and holding is being ensured.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is an explanatory view showing a section of a semiconductor manufacturing apparatus according to an embodiment;

FIG. 2 is an explanatory view illustrating an upper surface of the semiconductor manufacturing apparatus according to the embodiment;

FIG. 3 is an explanatory view depicting a preheating process step for the semiconductor manufacturing apparatus according to the embodiment;

FIG. 4 is an explanatory view showing a holding process step for the semiconductor manufacturing apparatus according to the embodiment;

FIG. 5 is a graph showing the manner of a rise in the temperature of a sapphire substrate at a test No. 9 in the embodiment;

FIG. 6 is a table illustrating an evaluation test result of sucking/holding of the post-preheat sapphire substrate in the embodiment;

FIG. 7 is a graph showing the manner of a rise in the temperature of the sapphire substrate at a test No. 2 in the embodiment; and

FIG. 8 is a graph depicting the dependence of temperature at the completion of preheating on a flow rate at an evaluation test in the embodiment.

### DETAILED DESCRIPTION OF THE PREFERRED EMBODIMENTS

Preferred embodiments illustrative of a semiconductor manufacturing apparatus and a manufacturing method of a semiconductor device according to the present invention will hereinafter be described with reference to the accompanying drawings.

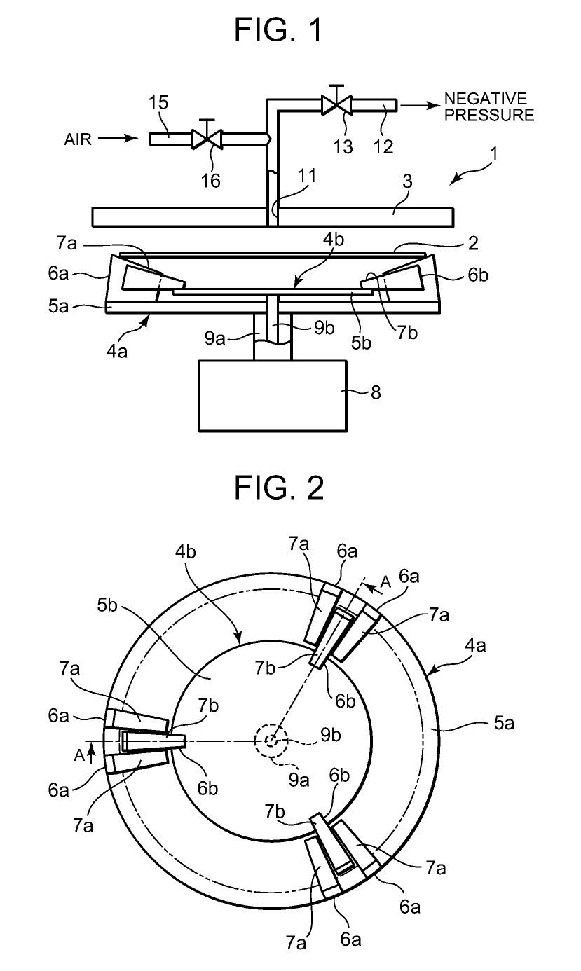

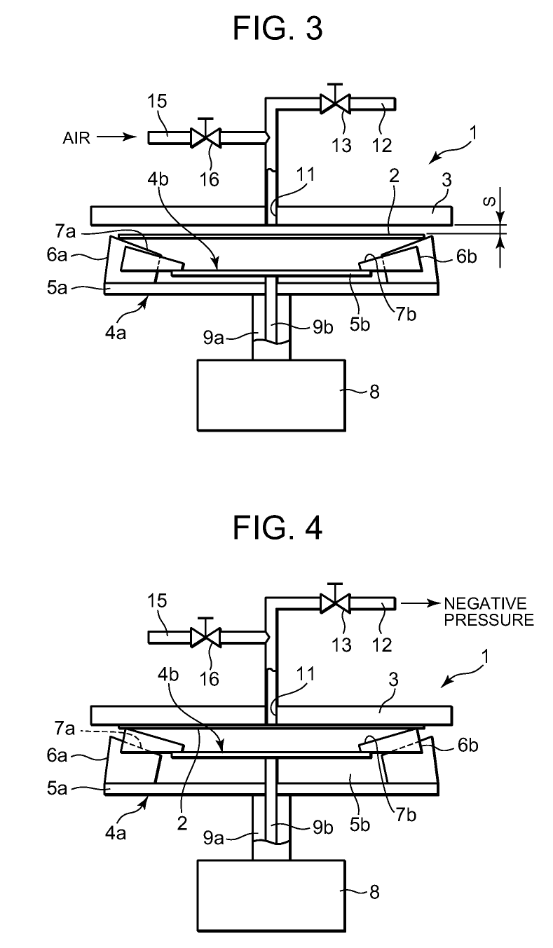

FIG. 1 is an explanatory view showing a section of a semiconductor manufacturing apparatus according to a preferred embodiment, and FIG. 2 is an explanatory view showing an upper surface of the semiconductor manufacturing apparatus according to the preferred embodiment.

Incidentally, FIG. 1 shows a section taken along sectional line A-A shown in FIG. 2. FIG. 2 is a top view showing a state in which a hot plate and a sapphire substrate shown in FIG. 1 have been eliminated.

In FIG. 1, reference numeral 1 indicates a semiconductor manufacturing apparatus, which is of a manufacturing apparatus employed in a process for manufacturing a semiconductor device in a state in which a sapphire substrate 2 is preheated at a relatively low atmospheric temperature in the atmosphere or the like thereby to heat up the sapphire substrate 2 used as a semiconductor substrate. The semiconductor manufacturing apparatus 1 according to the present embodiment is of an atmospheric pressure CVD apparatus.

The sapphire substrate 2 is of a substrate in which a thin-film semiconductor layer formed by epitaxially growing silicon (Si) or the like is laminated on the front surface of an insulated board comprised of a sapphire (Al₂O₃) crystal. For example, it is a circular thin plate having a diameter of 6 inches and a thickness ranging from 0.3 mm to 0.8 mm.

Reference numeral 3 indicates a hot plate, which is of a disk-like member having a diameter larger than that of the sapphire substrate 2 heated by an electric heater or the like. The hot plate 3 is disposed above the sapphire substrate 2 in opposition to the back surface of the sapphire substrate 2 supported by support portions 6a to be described later. The hot plate 3 heats up the sapphire substrate 2 and is used even as a process working table for the corresponding process step (deposition or film-forming process step in the present embodiment) carried out in a state in which the sapphire substrate 2 has been heated up.

Reference numeral 4a indicates a support table on which the pairs of prismatic support portions 6a comprised of silica glass or the like are mounted on an equi-arrangement basis in plural form (three pairs in the present embodiment) over an outer diameter portion of a disk-like support plate 5a having a diameter larger than that of the sapphire substrate 2 indicated by a chain double-dashed line in FIG. 2, which is disposed opposite to the hot plate 3. The support table 4a has the function of supporting the outer peripheral portion of the sapphire substrate 2 by slanting surfaces 7a provided at the support portions 6a without tilting the sapphire substrate 2.

Reference numeral 4b indicates a support table on which prismatic support portions 6b comprised of silica glass or the like, which are accommodated between the respective pairs of support portions 6a, are mounted on an equi-arrangement basis in plural form (three in the present embodiment) over an outer diameter portion of a disk-like support plate 5b having a diameter smaller than that of the support plate 5a, which is disposed on the hot plate 3 side of the support plate 5a of the support table 4a, as shown in FIG. 2. The support table 4b has the function of supporting an outer peripheral edge portion of the sapphire substrate 2 by tips or leading ends on the hot plate 3 side, of slating surfaces 7b provided at the support portions 6b without tilting the sapphire substrate 2.

The sapphire substrate 2 employed in the present embodiment is supported by the support portions 6a or 6b with its back surface being opposed to the hot plate 3.

In FIG. 1, reference numeral 8 indicates an elevating device which has the function of moving up and down a cylindrical elevation shaft 9a with the support table 4a joined to its leading end, and a columnar elevation shaft 9b inserted into the inner cylinder side of the elevation shaft 9a and having a leading end to which the support table 4b is joined, independently respectively. The elevating device 8 moves up and down the support portions 6a and 6b respectively provided on the support tables 4a and 4b by the elevation shafts 9a and 9b.

Reference numeral 11 indicates an intake/exhaust hole, which is a through hole formed by allowing the central part of the hot plate 3 to penetrate in its thickness direction. The intake/exhaust hole 11 functions as a suction hole which is connected to a negative pressure supply tube 12 for supplying negative pressure or vacuum, thereby to suck and hold the sapphire substrate 2 and also functions as a jet hole for jetting gas to be described later.

Reference numeral 13 indicates a negative pressure opening/closing valve, which is an ON/OFF valve for opening and closing a conduit of the negative pressure supply tube 12 connected to the intake/exhaust hole 11. The negative pressure opening/closing valve 13 has the function of controlling the supply and cut-off of negative pressure or vacuum supplied to the intake/exhaust hole 11 used as the suction hole.

Reference numeral 15 indicates a gas supply tube, which is coupled to the negative pressure supply tube 12 between the negative pressure opening/closing valve 13 and the intake/exhaust hole 11. The gas supply tube 15 is of a pipe for supplying gas such as nitrogen (N₂) gas jetted from the intake/exhaust hole 11 used as the jet hole.

Reference numeral 16 indicates a gas opening/closing valve, which is an ON/OFF valve for opening and closing a conduit of the gas supply tube 15. The gas opening/closing valve 16 has the function of controlling the supply and cut-off of gas which is supplied to the intake/exhaust hole 11 and whose flow rate is adjusted by an unillustrated flow control valve.

A process step for preheating the sapphire substrate 2 using the semiconductor manufacturing apparatus 1 having the above configuration, and a process step for holding the post-preheat sapphire substrate 2 will be explained below in accordance with processes indicated by P.

The sapphire substrate 2 employed in the present embodiment is of a substrate having a diameter of 6 inches and a thickness of 0.6 mm. The set temperature of the hot plate 3 is set to 380° C.

At a process P1, the back surface of the sapphire substrate 2 is placed on the slanting surfaces 7a of the support portions 6a on the support table 4a attached to the leading end of the elevation shaft 9a of the elevating device 8 with the back surface thereof being opposed to the lower surface o the hot plate 3 set to 380° C, thereby causing the slanting surfaces 7a of the support portions 6a to support the outer peripheral portion of the sapphire substrate 2.

At a process P2 (preheat process step), the elevation shafts 9a and 9b are simultaneously elevated by the elevating device 8 to raise the support tables 4a and 4b in the direction of the hot plate 3 and thereafter stop them at such a position that spacing or interval S defined between the back surface of the sapphire substrate 2 and the lower surface of the hot plate 3 is brought to a predetermined interval (2 mm in the present process).

Then, the gas opening/closing valve 16 is open-operated simultaneously with the stop of the sapphire substrate 2 to jet gas (nitrogen gas) having an ambient temperature, which is supplied from the gas supply tube 15 and whose flow rate has been adjusted or controlled to 29 liters/min (described as L/min) in the standard condition by the unillustrated flow control valve, from the intake/exhaust hole 11 used as the jet hole opened or defined in the central part of the hot plate 3 to the central part of the back surface of the sapphire substrate 2.

At this time, the temperature of the sapphire substrate 2 is raised by heat flowing from the back surface of the sapphire substrate 2 mainly through heat transfer via air heated by the hot plate 3. The central part of the sapphire substrate 2 is cooled by the gas jetted from the intake/exhaust hole 11, so that the rate of a rise in temperature is reduced.

At a process P3 (holding process step), the gas opening/closing valve 16 is close-operated after the elapse of two minutes from the start time of the preheat process step (the time of stop of the sapphire substrate 2 to the predetermined spacing S) thereby to stop the jetting of the gas from the intake/exhaust hole 11. Then, the elevation shaft 9b is elevated by the elevating device 8 to raise only the support table 4b attached to its leading end in the direction of the hot plate 3, thereby causing the back surface of the sapphire substrate 2 whose outer peripheral portion is supported by the leading ends of the support portions 6b to contact the lower surface of the hot plate 3. After the elapse of three minutes from the start time of the preheat process step, that is, after one minute from the stop of jetting of the gas, the negative pressure opening/closing valve 13 is open-operated to suck the sapphire substrate 2 by negative pressure supplied from the negative pressure supply tube 12 to the intake/exhaust hole 11 and hold the sapphire substrate 2 on the hot plate 3.

During the contact time of one minute, the entire sapphire substrate 2 is raised to a substantially uniform temperature and hence warpage of the sapphire substrate 2 is suppressed.

At a process P4, after the sapphire substrate 2 has been held, the elevation shafts 9a and 9b are lowered or moved down to return the support tables 4a and 4b to their original positions (refer to FIG. 1), thereby retracting the support portions 6a and 6b from the sapphire substrate 2. Then, the hot plate 3 having sucked and hold the sapphire substrate 2 is moved to a predetermined working position of the corresponding process (deposition process step in the present embodiment), where predetermined process working is done.

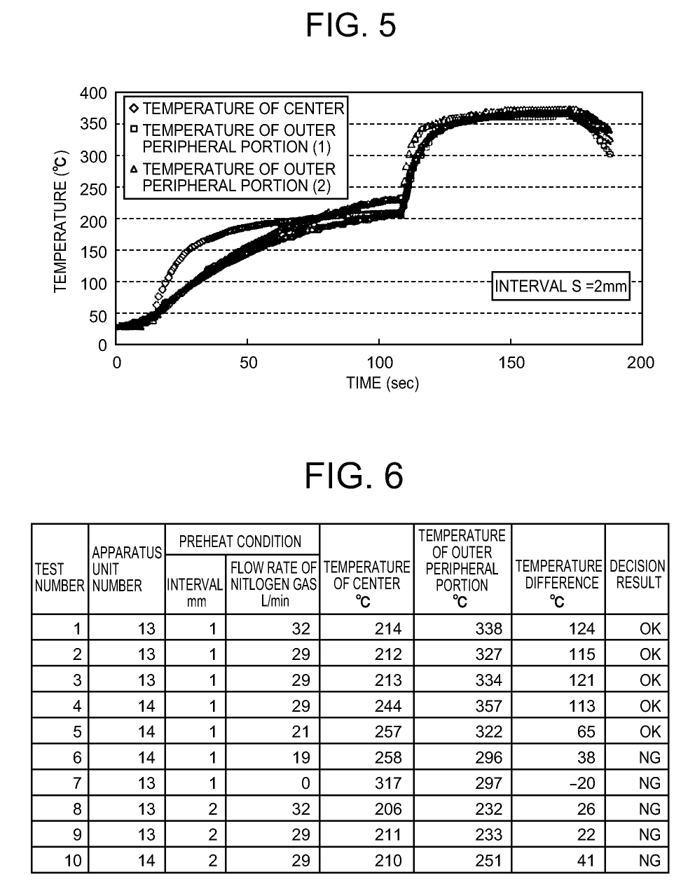

The manner of a rise in the temperature of the sapphire substrate 2 with the elapse of time under the preheat condition of the above process P2, i.e., where the predetermined spacing is assumed to be 2 mm and the jet amount of gas from the intake/exhaust hole 11 is assumed to be 29 L/min, is shown in FIG. 5.

The respective temperatures in this case were measured by a thermocouple provided in the center of the front surface of the sapphire substrate 2, and two thermocouples each provided at a position located on the center side by about 10 mm as viewed from the outer periphery of the outer peripheral edge portion.

It is understood that as shown in FIG. 5, the sapphire substrate 2 brought to approximately the ambient temperature upon the start time of the preheat process step at the process P2 is first heated at its central part with the elapse of time, so that the central part of the sapphire substrate 2 becomes higher than the outer peripheral edge portion, whereby the sapphire substrate 2 is warped in a convex bell-shape fashion toward the hot plate 3 once, whereas thereafter, the temperature thereof becomes lower than the outer peripheral edge portion with a decrease in the temperature rise rate due to the jetting of gas, so the sapphire substrate 2 is brought to a state of being warped in a concave bowl-shaped fashion toward the hot plate 3 after the elapse of two minutes, whereby the sapphire substrate 2 is brought approximately to an uniform temperature during the contact time of one minute at the process P3.

However, a decision result at the sucking and holding of the sapphire substrate 2 preheated under the preheat condition and during the contact time was ┌NG┘ due to the shortage of flatness.

This is considered due to the fact that although not apparent from FIG. 5, the temperature of the outer peripheral edge portion exposed to the ambient temperature during the contact time of one minute is slightly reduced because the amount of bowl-shaped warpage after the elapse of two minutes corresponding to the end condition of preheat is low, and correspondingly the sapphire substrate 2 is slightly warped in the bell-shaped fashion, and when the central part of the sapphire substrate 2 is adsorbed, the adsorbability of the outer peripheral edge portion is reduced and hence the slight warpage remains upon holding of the sapphire substrate 2.

Therefore, the dependence on the flatness at the suction/holding was evaluated with the predetermined spacing S and the jet amount of gas as parameters to make the preheat condition appropriate. The result of its evaluation test is shown in FIG. 6.

The evaluation test in this case was done using two semiconductor manufacturing apparatuses (machine/unit numbers 13 and 14) identical in spec and using nitrogen gas as the gas.

The respective temperatures shown in FIG. 6 are of temperatures after the elapse of two minutes from the start time of preheat. The temperature of the outer peripheral edge portion corresponds to the average value of temperatures measured by the two thermocouples.

Incidentally, the evaluation of the preheat condition shown in FIG. 5 is equivalent to one using the apparatus unit number 13, and the result of its evaluation is described in a test number 9.

As shown in FIG. 6, the result of determination of flatness at the suction/holding in an evaluation test indicated by a test number 2 at which the predetermined spacing S is set as 1 mm with the same flow rate of nitrogen gas using the same apparatus unit number 13 is represented as ┌OK┘. It has been suggested that the flatness of the sapphire substrate 2 at its suction/holding after the preheat depends on the predetermined spacing S.

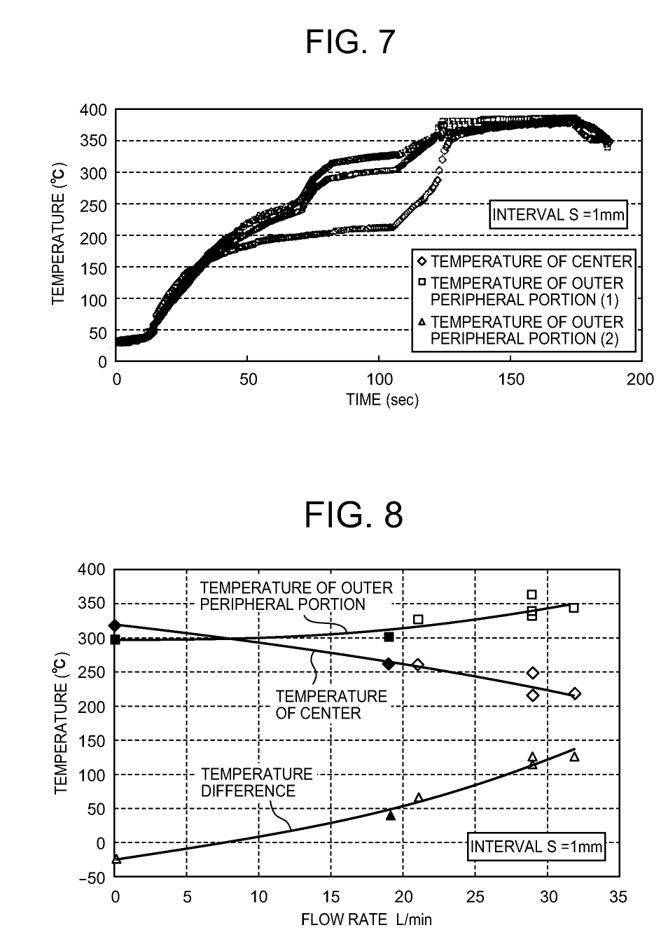

The manner of a rise in the temperature of the sapphire substrate 2 with the elapse of time under the preheat condition at the test number 2 is shown in FIG. 7.

It is understood that while the sapphire substrate 2 brought to approximately the ambient temperature upon the start time of the preheat process step at the process P2 is first heated at its central part with the elapse of time, so that the central part of the sapphire substrate 2 becomes higher than the outer peripheral edge portion, as shown in FIG. 7, the sapphire substrate 2 becomes immediately lower in temperature than the outer peripheral edge portion with a reduction in the temperature rise rate due to the jetting of gas and the difference in temperature becomes large as compared with the case shown in FIG. 5 after the elapse of two minutes (120 seconds), so the sapphire substrate 2 is brought to a state of being greatly warped in bowl-like form, whereby the temperature of the central part becomes slightly low during the contact time of one minutes at the process P3.

These differences mainly reside in the difference in the rise in the temperature of the outer peripheral edge portion. If the test numbers 2 and 9 shown in FIG. 6 are compared, then the temperature of the central part is equal therebetween, whereas the temperature of the outer peripheral edge portion differs like 327° C. and 233° C. As a result, the differences in temperature between the respective two result in 115° C. and 22° C. respectively and hence the amount of bowl-shaped warpage differs. Consequently, it is considered that the slight bowl-shaped warpage remains upon suction/holding and the flatness at the suction/holding has been ensured.

In order to confirm it, further comparison tests, i.e., a comparison test in which the flow rate of nitrogen gas is assumed to be identical as 32 L/min, and the spacing S is assumed to be 1 mm (test number 1) and 2 mm (test number 8) using the apparatus unit number 13, and a comparison test in which the flow rate of nitrogen gas is assumed to be identical as 29 L/min shown in FIG. 5 and the spacing S is assumed to be 1 mm (test number 4) and 2 mm (test number 10) using the apparatus unit number 14 are executed.

It is understood that even in any case containing the comparison between the test numbers 2 and 9 as apparent from the above, the decision result is given as ┌OK┘ where the spacing S is 1 mm and the decision result is given as ┌NG┘ where the spacing S is 2 mm, and the flatness of the post-preheat sapphire substrate 2 at its suction/holding depends on the spacing S between the hot plate 3 and the sapphire substrate 2 at the preheat process step.

Since it is thus understood that the flatness at the suction/holding is dependent on the spacing S, the dependence on the flow rate of nitrogen gas was next evaluated with the spacing S as 1 mm.

A graph showing the test numbers 1 through 7 of FIG. 6 and the dependence of their temperatures on the flow rate of nitrogen gas is shown in FIG. 8 as the result thereof.

Incidentally, open symbols shown in FIG. 8 respectively indicate the decision result ┌OK┘ shown in FIG. 6, and black symbols shown therein respectively indicate the decision result ┌NG┘.

It is understood that if the flow rate of nitrogen gas is increased as shown in FIG. 8 where the spacing S is assumed to be 1 mm, then the temperature at the completion of the preheat process step, mainly, the temperature of the central part is lowered and the difference between the temperature of the central part and that of the outer peripheral edge portion increases.

This shows that the above-described amount of bowl-shaped warpage depends on the flow rate of nitrogen gas. As is understood from FIG. 8, the lower limit of the flow rate thereof is 20 L/min and the central part temperature of the sapphire substrate 2 at that time is lower 65° C. or more than the temperature of the outer peripheral edge portion.

It is thus desirable that as a suitable preheat condition, the predetermined spacing S is set to 1 mm and the flow rate of nitrogen gas is set to 20 L/min or more. It is desirable that when the temperature of the central part is lower 65° C. or more than the temperature of the outer peripheral edge portion, the preheat end condition is set as the time when two minutes have elapsed after the setting of a preheat condition where no temperature measurement is made.

It is desirable that the contact time after the end of preheat is set to less than or equal to one minute (60 seconds).

If done in this way, then the preheat condition at the preheat process step is made appropriate, and the suction and holding of the sapphire substrate 2 to the hot plate 3 can be performed smoothly while the flatness at the suction/holding of the sapphire substrate 2 is being ensured.

Incidentally, it is desirable that the predetermined spacing S ranges from 0.7 mm or more to 1.2 mm or less. More preferably, the predetermined spacing S is desired to be 1 mm or less.

This is because when the spacing S is made narrower than 0.7 mm, the sapphire substrate 2 is likely to contact the hot plate 3 due to the bell-like warpage at the early stage of preheat, and when the spacing S is made wider than 1.2 mm, the outer peripheral edge portion is cooled so that it becomes difficult to ensure the difference in temperature between the central part and the outer peripheral edge portion.

As to the upper limit of the flow rate of nitrogen gas, a flow rate at which the bowl-like warpage becomes excessive due to the enlargement of a difference in temperature between the central part and the outer peripheral edge portion with an increase in the flow rate of nitrogen gas, thereby causing a crack or facture in the sapphire substrate 2, is preferably taken as an upper limit. In the present embodiment as described above, when the sapphire substrate is preheated from the back surface by the hot plate with the set temperature of 380° C., the preheat condition for the sapphire substrate is set assuming that the predetermined spacing S defined between the hot plate and the sapphire substrate is 1 mm or less and the jet amount of nitrogen gas from the intake/exhaust hole at the ambient temperature is 20 L/min or more, and the preheat end condition is set as the time when two minutes have elapsed when the temperature of the central part of the sapphire substrate becomes lower 65° C. or more than that of the outer peripheral edge portion or after the preheat condition has been set. Thus, the preheat condition at the preheat process step is made appropriate and the suction/holding of the sapphire substrate to the hot plate can be performed smoothly while the flatness of the sapphire substrate at its suction/holding is being ensured.

Incidentally, although the above embodiment has explained the gas jetted to control the temperature of the sapphire substrate as the nitrogen gas, any gas may be adopted if an inert gas such as Argon (Ar) is taken.

Although the above embodiment has described that the semiconductor substrate whose temperature is raised by the semiconductor manufacturing apparatus is of the sapphire substrate, the semiconductor substrate is not limited to it, but may be a semiconductor substrate such as an SOI substrate having an SOI structure in which a thin-film semiconductor layer comprised of silicon is formed in a silicon substrate with an embedded oxide film interposed therebetween. In short, if a semiconductor substrate which needs to jet gas for suppressing warpage in the preheat process step and needs to be deposited as for a sucked and held semiconductor substrate, is taken, then an advantageous effect similar to the above can be obtained even in the case of any semiconductor substrate.

Further, although the above embodiment has described the semiconductor manufacturing apparatus as the atmospheric pressure CVD apparatus, the semiconductor manufacturing apparatus is not limited to it, but may be a low pressure or pressure-reduced CVD apparatus or the like. In brief, if a semiconductor manufacturing apparatus which jets gas for suppressing warpage from an intake/exhaust hole upon preheating of a sapphire substrate and performs deposition on a semiconductor substrate sucked and held under negative pressure supplied to the intake/exhaust hole, is taken, then an advantageous effect similar to the above can be obtained even in the case of any semiconductor manufacturing apparatus.

While the preferred forms of the present invention have been described, it is to be understood that modifications will be apparent to those skilled in the art without departing from the spirit of the invention. The scope of the invention is to be determined solely by the following claims.

What is claimed is:

1. A method for manufacturing a semiconductor device using a semiconductor manufacturing apparatus including a hot plate for heating up a sapphire substrate in the atmosphere, support tables respectively provided with support portions, which support the sapphire substrate with the hot plat and a back surface of the sapphire substrate being opposite to each other, a jet hole provided in the hot plate and for jetting gas toward a central part of the sapphire substrate, and an elevating device for moving up and down the support tables, said method comprising the steps of:
causing the support portions to support the sapphire substrate with the back surface thereof being opposite to the hot plate;
elevating the support tables by the elevating device, stopping the same at a position where a spacing defined between the back surface of the sapphire substrate and the hot plate becomes 1 mm or less, and jetting a gas of 20 L/min or more toward the central part of the sapphire substrate through the jet hole; and
stopping the jetting of the gas from the jet hole when the temperature of the central part of the sapphire substrate becomes lower 65° C. or more than that of an outer peripheral edge portion thereof.

2. The method according to claim 1, further including the step of stopping the jetting of the gas from the jet hole after two minutes have elapsed since the start time of the preheat step in place of the step for stopping the jetting of the gas from the jet hole.

3. The method according to claim 1, wherein the set temperature of the hot plate is 380° C.
